(19) United States
(12) Patent Application Publication
(10) Pub. No.: US 2002/0109974 A1
(43) Pub. Date: Aug. 15, 2002

(54) Reduction of circuit board component exposure height

(76) Inventors: Fang-Yu Chu, Taipei City (TW); Yi-Lung Chen, Pan-Chian City (TW); Pao-Hsin Chiang, Taipei City (TW); Meng-Yu Jiang, Yungho City (TW); Yun-Liang Chu, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 09/779,505

(22) Filed: Feb. 9, 2001

(51) Int. Cl. H05K 7/14

(52) U.S. Cl. 361/796

(57) ABSTRACT

A primary circuit board is provided with an opening. A component is mounted on a secondary circuit board. The secondary circuit board is then mounted over the opening of the primary circuit board with the component disposed within the opening. An exposure height of the component over the primary circuit board is thus reduced, the exposure height being measured from a top surface of the component to a top surface of the primary circuit board.

### BACKGROUND OF THE INVENTION

1. Field of the Invention

The present invention relates to component heights on circuit boards. More specifically, the present invention discloses a method enabling smaller centerline offset values of a PCMCIA circuit board within a PCMCIA card.

2. Description of the Prior Art

The miniaturization of electronic components has led to successively smaller devices. In concert with this, standards are being created with successively smaller physical dimensions. Personal computer memory card international association (PCMCIA) cards are an example of this, and are most commonly used in portable computers. The PCMCIA standard requires that the total thickness of a PCMCIA card not exceed 5 millimeters (mm). Years ago, meeting this requirement would have been considered a daunting task. Today, it is accepted as the norm.

Please refer to FIG. 1. FIG. 1 is a simple cross-sectional view of a PCMCIA card 10. The PCMCIA card 10 comprises a top casing 12, a bottom casing 14 and a circuit board 16. The total thickness of the PCMCIA card 10 is indicated by arrow 10A, and is 5.00 mm. However, both the top casing 12 and bottom casing 14 have a thickness of 0.41 mm, as indicated by arrows 10B. Thus, the total usable space between the top and bottom casings 12 and 14 is 4.18 mm, and is indicated by arrow 10D. The PCMCIA card 10 has a centerline 10CL, which is midway between the top casing 12 and bottom casing 14. The centerline 10CL is thus located 2.09 mm from both a top surface 14t of the bottom casing 14, and from a bottom surface 12b of the top casing 12. This centerline distance is indicated by arrows 10CD.

Ideally, a top surface 16t of the circuit board 16 should be located on the centerline 10CL. This is due to manufacturing considerations. It is considerably cheaper to manufacture the PCMCIA card 10 when the top surface 16t of the circuit board 16 lies on the centerline 10CL. This is not always possible, however. A component 18 with an excessive exposure height may be mounted on the circuit board 16 that forces an offset of the circuit board 16. The exposure height of the component 18 is the height of a top surface 18t of the component 18 above the top surface 16t of the circuit board 16, and is indicated by arrow 10E. The offset is the distance of the top surface 16t of the circuit board 16 from the centerline 10CL, and is indicated by arrow 10F. In the example of FIG. 1, the component 18 has an exposure height of about 2.60 mm, which greatly exceeds the available width of 2.09 mm for the centerline distance 10CD. Consequently, to accommodate the component 18, it is necessary to have the offset 10F. For manufacturing purposes, the offsets 10F come in steps of 0.3 mm, and each successive step of 0.3 mm for the offset 10F leads to correspondingly more expensive production costs for the PCMCIA card 10. The PCMCIA card 10 must use two 0.3 mm offset steps to accommodate the component 18, leading to the 0.6 mm offset 10F. Thus, the PCMCIA card 10 is more expensive to produce than an equivalent card that has a single offset 10F of only 0.3 mm, or, better still, no offset 10F at all.

### SUMMARY OF THE INVENTION

It is therefore a primary objective of this invention to provide a method for reducing the exposure height of a component above a primary circuit board, and thus to reduce, or completely eliminate, an offset of the primary circuit board in a PCMCIA card.

To achieve this objective, the method of the present invention, briefly summarized, utilizes a secondary circuit board. The primary circuit board is provided with an opening. The component is mounted on the secondary circuit board. The secondary circuit board is then mounted over the opening of the primary circuit board with the component disposed within the opening. The exposure height of the component over the primary circuit board is thus reduced.

It is an advantage of the present invention that by reducing the exposure height of the component with respect to the primary circuit board, the offset of the primary circuit board within the PCMCIA card can be reduced. This, in turn, leads to reduced manufacturing costs for the PCMCIA card.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 is a simple cross-sectional view of a prior art PCMCIA card.

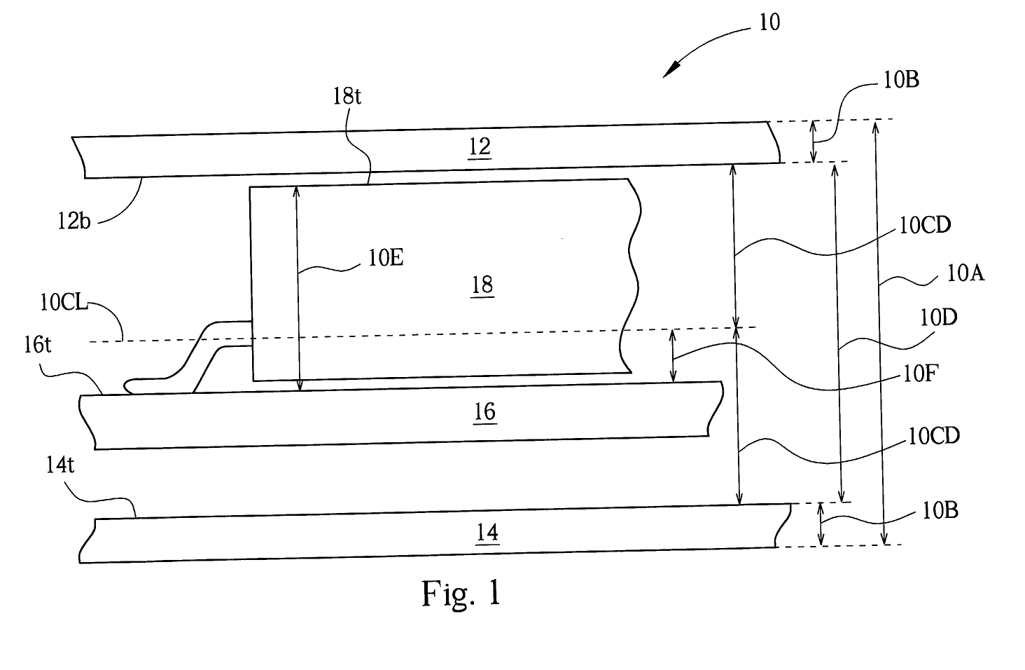

FIG. 2 is an exploded side view of a first circuit utilizing the method of the present invention.

FIG. 3 is an exploded side view of a second circuit utilizing the method of the present invention.

FIG. 4 is a simple cross-sectional view of a present invention PCMCIA card.

### DETAILED DESCRIPTION OF THE PREFERRED EMBODIMENT

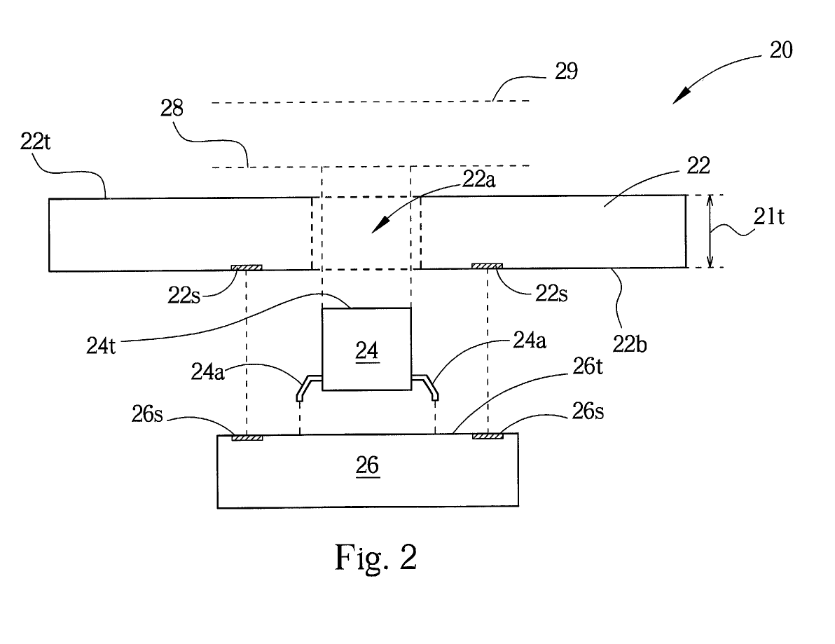

It is the method of the present invention to mount a component on a secondary circuit board. The secondary circuit board is then mounted over an opening of a primary circuit board, the component being disposed within the opening, to reduce the exposure height of the component with respect to the primary circuit board. Please refer to FIG. 2. FIG. 2 is an exploded side view of a circuit 20 utilizing the method of the present invention. The circuit 20 comprises a primary circuit board 22, a component 24 and a secondary circuit board 26. The primary circuit board 22 comprises an opening 22a and a plurality of surface contacts 22s. The secondary circuit board 26 also comprises a plurality of surface contacts 26s, which are in juxtaposition with the surface contacts 22s. That is, the positions of the surface contacts 26s correspond to the positions of the surface contacts 22s. When a top surface 26t of the secondary circuit board 26 is brought into contact with a bottom surface 22b of the primary circuit board 22, each surface contact 26s will be aligned with a respective surface contact 22s. The surface contacts 22s and 26s are used to solder the secondary circuit board 26 to the primary circuit board 22. Surface mounting technology (SMT) is used to mount the component 24 onto the secondary circuit board 24. SMT is the preferred process as SMT mounts the component 24 much closer to the top surface 26t of the secondary circuit board 26. Other methods are also possible, however, such as dual in-line packaging (DIP) technology. Leads 24a from the component 24 are thus soldered onto the top surface 26t of the secondary circuit board 26, and are placed into electrical contact with the surface contacts 26s. When the secondary circuit board 26 is soldered to the primary circuit board 22, the component 24 establishes electrical connection with the primary circuit board 22 through the surface contacts 26s and 22s. Additionally, and of key importance to the present invention, when the secondary circuit board 26 is mounted onto the primary circuit board 22, the component 24 is disposed within the opening 22a. A top surface 24t of the component 24 may thus protrude through the opening 22a with a fixed height above a top surface 22t of the primary circuit board 22. This height is indicated by the dashed line 28, and is the exposure height of the component 24 with respect to the primary circuit board 22. Dotted line 29 indicates the exposure height of the component 24 if the component 24 were mounted directly onto the top surface 22t of the primary circuit board 22. Clearly, the exposure height 28 of the present invention method is less than the conventional exposure height 29. The primary circuit board 22 has a thickness indicated by arrow 21t. The conventional exposure height 29 is thus reduced by about the thickness 21t with the method of the present invention to yield the exposure height 28. To ease production and manufacturing costs, it is envisioned that the secondary circuit board 26 has an internal structure that is similar, or identical to, the primary circuit board 22. The secondary circuit board 26 thus has a thickness that is nearly identical to that of the primary circuit board 22.

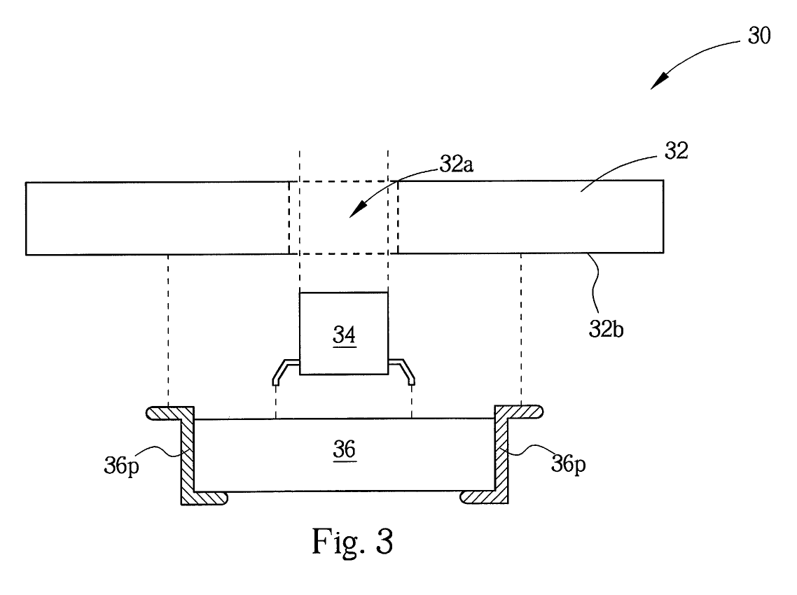

Please refer to FIG. 3. FIG. 3 is an exploded side view of a circuit 30 utilizing the method of the present invention. The circuit 30 is nearly identical in nature to the circuit 20, and comprises a primary circuit board 32 with an opening 32a, and a component 34 mounted on a secondary circuit board 36. The circuit 30 differs from the circuit 20 in that SMT is used to mount the secondary circuit board 36 to the primary circuit board 32. To effect this, the secondary circuit board 36 comprises a plurality of pins 36p that are electrically connected to the component 34. SMT is used to solder the pins 36p to a bottom surface 32b of the primary circuit board 32. Once the secondary circuit board 36 is mounted over the opening 32a of the primary circuit board 32, the component 34 will lay disposed within the opening 32a, and thus have a reduced exposure height with reference to the primary circuit board 32.

In both the circuit 20 and the circuit 30, the components 24 and 34 may be any sort of electrical component, be it either a passive or an active device. In particular, the component 24 or 34 may be an integrated circuit (IC) package.

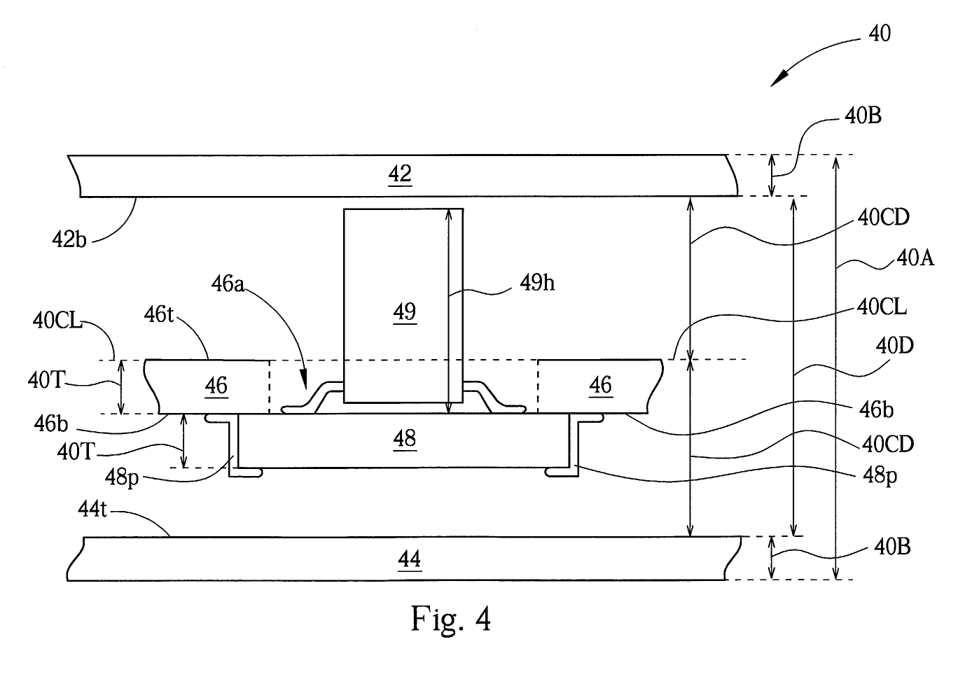

Please refer to FIG. 4. FIG. 4 is a simple cross-sectional view of a present invention PCMCIA card 40. The PCMCIA card 40 comprises a top casing 42, a bottom casing 44, a primary circuit board 46, a secondary circuit board 48 and a component 49. The method of the present invention is used and the primary circuit board 46 thus has an opening 46a over which the secondary circuit board 48 is mounted. The component 49 is mounted on the secondary circuit board 48 and is disposed in, and protrudes through, the opening 46a. The total thickness of the PCMCIA card 40 is indicated by arrow 40A, and is 5.00 mm. Both the top casing 42 and bottom casing 44 have a thickness of 0.41 mm, as indicated by arrows 40B. The total usable space between the top and bottom casings 42 and 44 is thus 4.18 mm, and is indicated by arrow 40D. The PCMCIA card 40 has a centerline 40CL, which is midway between the top casing 42 and bottom casing 44. The centerline 40CL is thus located 2.09 mm from both a top surface 44t of the bottom casing 44, and from a bottom surface 42b of the top casing 42. This centerline distance is indicated by arrows 40CD. Both the primary circuit board 46 and the secondary circuit board 48 have a thickness of 0.6 mm, which is indicated by the arrows 40T. The component 49 has a component height of 2.6 mm, which is indicated by arrow 49h, and would normally necessitate two 0.3 mm offset steps of the primary circuit board 46 from the centerline 40CL, as the component height 49h exceeds the centerline distance 40CD by 0.51 mm. However, with the method of the present invention, an additional 0.6 mm is obtained from the thickness 40T of the primary circuit board 46, and thus no offset is required of the primary circuit board 46. Utilizing the method of the present invention, a top surface 46t of the primary circuit board 46 is able to be disposed closer, and, in fact, on the centerline position 40CL.

In the preferred embodiment, SMT is used to electrically connect both the component 49 to the secondary circuit board 48, and to electrically connect the secondary circuit board 48 to the primary circuit board 46. The secondary circuit board 48 thus comprises a plurality of pins 48p, which are soldered to a bottom surface 46b of the primary circuit board 46, and which are electrically connected to the component 49. In this manner, the component 49 is electrically connected to the primary circuit board 46. Other mounting processes are possible, though, such as surface contacts as disclosed in FIG. 2. Additionally, the component 49 may be any sort of electrical device, and, in particular may be an IC package. For example, if the PCMCIA card 40 is to provide Bluetooth wireless functionality to a computer, then the component 49 may be an IC package that contains Bluetooth-related circuitry.

It should be clear to one skilled in the art that the fact that the particular example in hand of FIG. 4 requires no offsets for the primary circuit board 46 is simply a special case of the geometry of the example. Other component heights 49h may require one, two or more 0.3 mm offset steps to accommodate the component 49 within the PCMCIA card 40. Nevertheless, the number of such steps will be reduced by the present invention if the thickness 40T of the primary circuit board 46 is sufficient.

In contrast to the prior art, the present invention provides an opening in the primary circuit board, and a secondary circuit board mounted over the opening. A component is mounted on the secondary circuit board, and is disposed within the opening. The exposure height of the component with respect to the primary circuit board is thus reduced.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for reducing an exposure height of a component, the exposure height being measured from a top surface of a primary circuit board to a top surface of the component, the method comprising:
providing an opening in the primary circuit board;
mounting the component on a secondary circuit board; and
mounting the secondary circuit board onto the primary circuit board, the component disposed within the opening.

2. The method of claim 1 wherein the secondary circuit board is electrically connected to the primary circuit board.

3. The method of claim 2 wherein the secondary circuit board comprises a plurality of surface contacts that are used as soldering points for corresponding surface contacts on the primary circuit board.

4. The method of claim 2 wherein the secondary circuit board comprises a plurality of pins that are used as soldering points to solder the secondary circuit board to the primary circuit board.

5. The method of claim 4 wherein surface mounting technology (SMT) is used to electrically connect the secondary circuit board to the primary circuit board.

6. The method of claim 1 wherein the component is an integrated circuit (IC) package.

7. The method of claim 6 wherein surface mounting technology (SMT) is used to mount the IC package onto the secondary circuit board.

8. The method of claim 6 wherein the IC package contains Bluetooth-related circuitry.

9. The method of claim 1 wherein the primary circuit board has a first thickness, and the exposure height of the component is reduced by an amount that is approximately equal to the first thickness.

10. The method of claim 8 wherein the secondary circuit board has a second thickness that is approximately equal to the first thickness.

11. A method for adjusting an offset value of a primary circuit board disposed within a personal computer memory card international association (PCMCIA) card, the offset value measuring a distance from a centerline of the PCMCIA card to a top surface of the primary circuit board and being necessitated due to a height of a component within the PCMCIA card, the method comprising:
providing an opening in the primary circuit board;
mounting the component on a secondary circuit board; and
mounting the secondary circuit board onto the primary circuit board, the component disposed within the opening;
wherein the disposition of the component within the opening reduces a height of a top surface of the component from the top surface of the primary circuit board.

12. The method of claim 11 wherein the secondary circuit board is electrically connected to the primary circuit board.

13. The method of claim 12 wherein the secondary circuit board comprises a plurality of surface contacts that are used as soldering points for corresponding surface contacts on the primary circuit board.

14. The method of claim 12 wherein the secondary circuit board comprises a plurality of pins that are used as soldering points to solder the secondary circuit board to the primary circuit board.

15. The method of claim 14 wherein surface mounting technology (SMT) is used to electrically connect the secondary circuit board to the primary circuit board.

16. The method of claim 11 wherein the component is an integrated circuit (IC) package.

17. The method of claim 16 wherein surface mounting technology (SMT) is used to mount the IC package onto the secondary circuit board.

18. The method of claim 16 wherein the IC package contains Bluetooth-related circuitry.

19. The method of claim 11 wherein a thickness of the secondary circuit board is approximately equal to a thickness of the primary circuit board.

20. A personal computer memory card international association (PCMCIA) card comprising:
a casing with a centerline position;
a primary circuit board with an opening;
a secondary surface board mounted over the opening; and
a component mounted on the secondary circuit board and disposed within the opening;
wherein the disposition of the component within the opening enables a top surface of the primary circuit board to be disposed within the casing closer to the centerline position.

21. The PCMCIA card of claim 20 wherein the secondary circuit board is electrically connected to the primary circuit board.

22. The PCMCIA card of claim 21 wherein the secondary circuit board comprises a plurality of surface contacts that are used as soldering points for corresponding surface contacts on the primary circuit board.

23. The PCMCIA card of claim 21 wherein the secondary circuit board comprises a plurality of pins that are used as soldering points to solder the secondary circuit board to the primary circuit board.

24. The PCMCIA card of claim 23 wherein surface mounting technology (SMT) is used to electrically connect the secondary circuit board to the primary circuit board.

25. The PCMCIA card of claim 20 wherein the component is an integrated circuit (IC) package.

26. The PCMCIA card of claim 25 wherein surface mounting technology (SMT) is used to mount the IC package onto the secondary circuit board.

27. The PCMCIA card of claim 25 wherein the IC package contains Bluetooth-related circuitry.

28. The PCMCIA card of claim 20 wherein a thickness of the secondary circuit board is approximately equal to a thickness of the primary circuit board.
